(19) United States
(12) Patent Application Publication
(10) Pub. No.: US 2026/0236646 A1
(43) Pub. Date: Aug. 13, 2026

(54) SYSTEMS AND METHODS FOR TRAINING PREDICTIVE MODELS USING GRAPH-BASED TECHNIQUES

(71) Applicant: Schlumberger Technology Corporation, Sugar Land, TX (US)

(72) Inventor: Soham Sheth, Abingdon (GB)

(21) Appl. No.: 19/474,739

(22) PCT Filed: Apr. 12, 2024
(86) PCT No.: PCT/US2024/024421

§ 371 Date: Oct. 13, 2025

Related U.S. Application Data
(60) Provisional application No. 63/496,128, filed on Apr. 14, 2023.

(51) Int. Cl. G06F 30/27; G06F 30/28

(52) U.S. Cl. CPC G06F 30/27; G06F 30/28

(57) ABSTRACT

A method includes receiving image data including a plurality of cells corresponding to a plurality of measured fluid properties of a subterranean region. The method also includes generating a plurality of nodes based on the plurality of cells, wherein each node of the plurality of nodes comprises relational information related to at least a portion of an arrangement of the plurality of cells. Further, the method includes generating a graph-based representation of the plurality of cells based on the plurality of nodes. Further still, the method includes generating a predicted graph-based representation of one or more fluid properties of the subterranean region over time based on a model of fluid properties in the subterranean region and the graph-based representation. Even further, the method includes adjusting one or more operation of one or more fluid systems associated with the subterranean region based on the predicted graph-based representation.

### CROSS-REFERENCE TO RELATED APPLICATION

This application claims priority to U.S. Provisional Application No. 63/496,128, filed on Apr. 14, 2023, which is hereby incorporated by reference in its entirety.

### INTRODUCTION

This disclosure relates generally to generating a model used for oil and gas operations using a graph-based training technique.

### BACKGROUND

This section is intended to introduce the reader to various aspects of art that may be related to various aspects of the present disclosure, which are described and/or claimed below. This discussion is believed to help provide the reader with background information to facilitate a better understanding of the various aspects of the present disclosure. Accordingly, it is understood that these statements are to be read in this light, and not as admissions of prior art.

Reservoir simulation is a numerical method used to model fluid flow processes in porous media. As such, reservoir simulation corresponds to an integral stage in field development planning workflows ranging from water flood optimization scenarios to new energy and carbon capture and storage solutions. The reservoir simulator may be used to predict how the fluid interacts with the rock in the subsurface. For most applications, the simulator may be executed thousands of times to facilitate a robust decision-making process. As a result, numerical simulators may be inefficient in terms of time and computing resources (e.g., energy, processing). Accordingly, improvements in developing proxy models that are able to produce results that are similar to numerical simulators are desirable.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Certain embodiments of the present disclosure include a method. The method includes receiving image data comprising a plurality of cells corresponding to a plurality of measured fluid properties of a subterranean region. The method also includes generating a plurality of nodes based on the plurality of cells, wherein each node of the plurality of nodes comprises relational information related to at least a portion of an arrangement of the plurality of cells. Further, the method includes generating a graph-based representation of the plurality of cells based on the plurality of nodes. Further still, the method includes generating a predicted graph-based representation of one or more fluid properties of the subterranean region over time based on a model of fluid properties in the subterranean region and the graph-based representation. Even further, the method includes adjusting one or more operation of one or more fluid systems associated with the subterranean region based on the predicted graph-based representation.

Certain embodiments of the present disclosure include a non-transitory, computer-readable medium storing instructions executable by a processor of a computing device. The instructions comprise instructions to receive image data comprising a plurality of cells corresponding to a plurality of measured fluid properties of a subterranean region. The instructions also include instructions to generate a plurality of nodes based on the plurality of cells, wherein each node of the plurality of nodes comprises relational information related to at least a portion of an arrangement of the plurality of cells. Further, the instructions include instructions to generate a graph-based representation of the plurality of cells based on the plurality of nodes. Further still, the instructions include instructions to generate a predicted graph-based representation of one or more fluid properties of the subterranean region over time based on a model of fluid properties in the subterranean region and the graph-based representation. Even further, the instructions include instructions to adjust one or more operation of one or more fluid systems associated with the subterranean region based on the predicted graph-based representation.

Certain embodiments of the present disclosure include a system. The system includes at least one memory and at least one processor configured to execute stored instruction to perform actions include receiving image data comprising a plurality of cells corresponding to a plurality of measured fluid properties of a subterranean region. The actions also include generating a plurality of nodes based on the plurality of cells, wherein each node of the plurality of nodes comprises relational information related to at least a portion of an arrangement of the plurality of cells. Further, the actions include generating a graph-based representation of the plurality of cells based on the plurality of nodes. Further still, the actions include generating a predicted graph-based representation of one or more fluid properties of the subterranean region over time based on a model of fluid properties in the subterranean region and the graph-based representation. Even further, the actions include adjusting one or more operation of one or more fluid systems associated with the subterranean region based on the predicted graph-based representation.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a schematic diagram of a fluid system with a subterranean control system used to determine one or more fluid properties of a subsurface formation, in accordance with an embodiment of the present techniques;

FIG. 2 illustrates a block diagram of various components that may be part of the subterranean control system of FIG. 1, in accordance with an embodiment of the present techniques;

FIG. 3 is a flow diagram of an example method for generating a predictive model using graph-based training techniques, in accordance with an embodiment of the present techniques;

FIG. 4 illustrates an image and a graph-based representation of the image, in accordance with an embodiment of the present techniques;

FIG. 5 shows graph-based representations corresponding to a reservoir, in accordance with an embodiment of the present techniques;

FIG. 6 shows graph-based representations corresponding to a reservoir, in accordance with an embodiment of the present techniques; and

FIG. 7 shows a flow diagram of an example method for adjusting one or more operations of a fluid system using a graph-based representation that corresponds to image data.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The drawing figures are not necessarily to scale. Certain features of the embodiments may be shown exaggerated in scale or in somewhat schematic form, and some details of conventional elements may not be shown in the interest of clarity and conciseness. Although one or more embodiments may be preferred, the embodiments disclosed should not be interpreted, or otherwise used, as limiting the scope of the disclosure, including the claims. It is to be fully recognized that the different teachings of the embodiments discussed may be employed separately or in any suitable combination to produce desired results. In addition, one skilled in the art will understand that the description has broad application, and the discussion of any embodiment is meant only to be exemplary of that embodiment, and not intended to intimate that the scope of the disclosure, including the claims, is limited to that embodiment.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. It should be noted that the term “multimedia” and “media” may be used interchangeably herein.

Oil and gas operations are improved by data from a variety of sources. For example, an operator may select suitable locations to drill a well based on reservoir data. In general, the reservoir data may indicate a presence and/or amount of certain fluids within a subterranean region, wherein the fluids may include hydrocarbon fluids (e.g., oil and natural gas), water, brine, brackish fluids, and the like. However, the presence and/or amount of the fluids changes over time due to external factors, such as drilling in a nearby well, absorption of the fluids into porous media, and the like. As such, it can be difficult to accurately use reservoir data to inform oil and gas decisions. Accordingly, it may be advantageous to develop a predictive model for reservoir simulations that provides insights into how fluid properties of the reservoir may change over time.

For example, it may be desirable to train a predictive model for reservoir simulations such that an enterprise may utilize insights gained from the reservoir simulations to efficiently recover resources from a subterranean formation. However, training such a model is difficult due to the non-linearity of the conservation equations. Certain models, such as auto-encoder architectures, may be useful for predictive modeling of subterranean properties, such as fluid properties. However, training such models may consume a relatively large amount of time and computing resources (e.g., processing power, time).

As mentioned above, a predictive model for a reservoir may be used to inform certain oil and gas decisions, such as suitable locations to drill. For example, the predictive model may be trained with image data where the number of pixels in an image is dictated by the size of the discretized computational mesh. In such examples, the number of pixels may be between 5 to 10 million cells. Thus, training the predictive model using such large meshes could take days to weeks for one model, which may not be suitable for oil and gas operations and storage operations such as carbon capture, utilization and storage (CCUS) and hydrogen storage. An oil and gas operation may benefit from predictive modeling on a relatively shorter timescale, such as minutes, hours, or days. As such, certain techniques for training models may not be suitable for certain types of data (e.g., fluid property) that may offer valuable insights for oil and gas decisions. As such, a solution is needed to provide more efficient training for fluid property model for analyzing image data associated with fluid systems.

Accordingly, the present disclosure is directed to systems and methods for training of a subsurface model or subterranean model using graph-based training techniques. In general, the disclosed techniques include training a predictive model by transforming data (e.g., image data) of measured fluid and/or rock properties or conditions into a graph-based representation. The graph-based representation includes multiple nodes having characteristics (e.g., attributes) related to measured fluid properties and corresponding regions, locations, or areas of a subsurface or subterranean fluid region, such as a reservoir. For example, image data of measured fluid properties may include a mesh of cells, where each cell corresponds to a position in a reservoir. The measured fluid properties may include saturation, pressure, temperature, dielectric constant, and other measurable properties, such as permeability and/or porosity values in each cell. As referred to herein, the graph-based representation a collection of nodes that store the information indicate the relative arrangement of the nodes. Compared to image data that includes a plurality of cells in a particular arrangement to form a volume or surface (e.g., corresponding to a subterranean fluid region), the graph-based representation includes nodes that store information (e.g., attributes) that indicate the relative arrangement of the nodes, and thus, preserve information related to the cells of the original image data. At least in some instances, training a subterranean model using image data may be difficult and/or utilize a large amount of computational resources. For example, it may be difficult to train a subterranean model for structurally complex regions, such as regions where a horizon may vary vertically or otherwise have an irregular geometry. It should be noted that the disclosed graph-based training techniques may be used to train a predictive model with two-dimensional (2D) and/or three-dimensional (3D) image data corresponding to a subsurface or subterranean fluid region. It is presently recognized that transforming the cells into a graph-based representation may reduce the amount of computational resources to train a subterranean model, while still preserving spatial information between the cells of the image data. It should be noted that the disclosed techniques may be applied to various fluid systems, such as hydrogen storage systems, carbon capture and sequestration (CCS) systems, safety valves, fluid sampling systems, and the like. In this way, the graph-based training techniques may accelerate the interpretation process of subterranean regions used to inform oil and gas decisions and storage operations such as carbon capture, utilization and storage (CCUS) and hydrogen storage.

The disclosed techniques include using a proxy model based on a graph convolution network. The proxy model may predict the spatial and temporal evolution of state variables (e.g., measured fluid properties), such as pressure and saturations, in the subsurface given different perturbations to the wells (e.g., well controls). The training data is generated using a reservoir simulator (e.g., a numerical simulator) by running simulations for an ensemble of well controls and extracting the pressure and saturation fields at each reporting step.

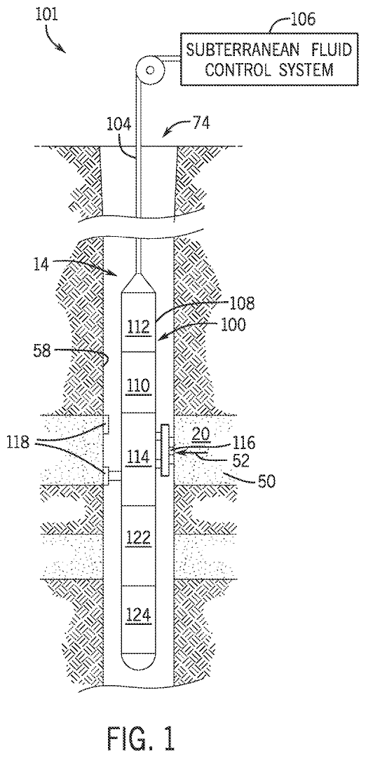

With the foregoing in mind, FIG. 1 depicts an example of a wireline downhole tool 100 of a fluid system 101 that may employ the systems and techniques described herein to determine information related to the reservoir fluid 50. The wireline downhole tool 100 is suspended in the wellbore 14 from the lower end of a multi-conductor cable 104 that is spooled on a winch at the surface 74. Similar to the downhole acquisition tool 12, the wireline downhole tool 100 may be conveyed on wired drill pipe, a combination of wired drill pipe and wireline, or other suitable types of conveyance. The cable 104 is communicatively coupled to a subterranean fluid control system 106. The wireline downhole tool 100 includes an elongated body 108 that houses modules 110, 112, 114, 122, and 124 that provide various functionalities including imaging, fluid sampling, fluid testing, operational control, and communication, among others. For example, the modules 110 and 112 may provide additional functionality such as fluid analysis, resistivity measurements, operational control, communications, coring, and/or imaging, among others.

As shown in FIG. 1, the module 114 is a fluid communication module 114 that has a selectively extendable probe 116 and backup pistons 118 that are arranged on opposite sides of the elongated body 108. The extendable probe 116 is configured to selectively seal off or isolate selected portions of the wall 58 of the wellbore 14 to fluidly couple to the adjacent geological formation 20 and/or to draw fluid samples from the geological formation 20. The probe 116 may include a single inlet or multiple inlets designed for guarded or focused sampling. The reservoir fluid 50 may be expelled to the wellbore through a port in the body 108 or the formation fluid 50 may be sent to one or more modules 122 and 124. The modules 122 and 124 may include sample chambers that store the reservoir fluid 50. In the illustrated example, the subterranean fluid control system 106 and/or a downhole control system are configured to control the extendable probe assembly 116 and/or the drawing of a fluid sample from the formation 20 to enable analysis of the fluid properties of the reservoir fluid 50, as discussed above. In some embodiments, the wireline downhole tool 100 may include one or more light sources and/or light detectors disposed along a fluid conduit of the wireline downhole tool 100 to facilitate acquiring fluid property data (e.g., saturation data, pressure data, and the like) of the reservoir fluid 50.

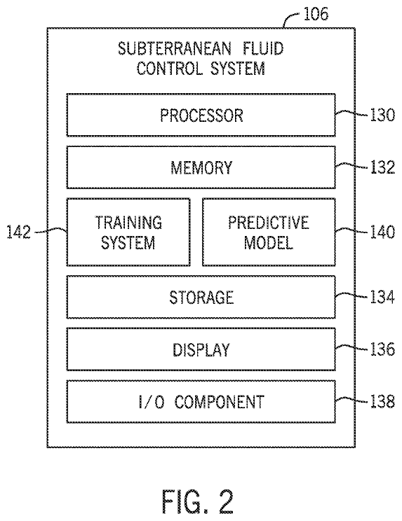

In certain embodiments, the sensors within the downhole tool 12 may collect and transmit data associated with the characteristics of the geological formation 20 and/or the fluid properties and the composition of the reservoir fluid 50 to a subterranean fluid control system 106 at surface 74, where the data may be stored and processed in the subterranean fluid control system 106 One embodiment of the subterranean fluid control system 106 is shown in FIG. 2. In general, the subterranean fluid control system 106 may be used to control operations of components or equipment associated with fluid systems such as hydrogen storage systems, CCS systems, safety valves, fluid sampling systems, and the like. As illustrated, the subterranean fluid control system 106 may include a processor 130, memory 132, storage 134, and display 136 and/or input/output (I/O) components 138. The memory 132 may include one or more tangible, non-transitory, machine readable media collectively storing one or more sets of instructions for operating the downhole tool 12, determining formation characteristics (e.g., geometry, connectivity, minimum horizontal stress, etc.) calculating and estimating fluid properties of the reservoir fluid 50, modeling the fluid behaviors using, e.g., equation of state models (EOS). The memory 132 may store reservoir modeling systems (e.g., geological process models, petroleum systems models, reservoir dynamics models, etc.), mixing rules and models associated with compositional characteristics of the reservoir fluid 50, equation of state (EOS) models for equilibrium and dynamic fluid behaviors (e.g., biodegradation, gas/condensate charge into oil, CO2 charge into oil, fault block migration/subsidence, convective currents, among others not related to methane hydrate), and any other information that may be used to determine geological and fluid characteristics of the geological formation 20 and reservoir fluid 52, respectively. In certain embodiments, the subterranean fluid control system 106 may apply filters to remove noise from the data.

To process the data, the processor 130 may execute instructions stored in the memory 132 and/or storage 134. For example, the instructions may cause the processor to compare the data (e.g., from the logging while drilling and/or downhole analysis) with known reservoir properties estimated using the reservoir modeling systems, use the data as inputs for the reservoir modeling systems, and identify geological and reservoir fluid properties that may be used for exploration and production of the reservoir. As such, the memory 132 and/or storage 134 of the subterranean fluid control system 106 may be any suitable article of manufacture that can store the instructions. By way of example, the memory 132 and/or the storage 134 may be ROM memory, random-access memory (RAM), flash memory, an optical storage medium, or a hard disk drive. The display 136 may be any suitable electronic display that can display information (e.g., logs, tables, cross-plots, reservoir maps, etc.) relating to properties of the well/reservoir (e.g., subterranean reservoir) as measured by the downhole tool 12. It should be appreciated that, although the subterranean fluid control system 106 is shown by way of example as being located at the surface 74, the subterranean fluid control system 106 may be located in the downhole tool 12. In such embodiments, some of the data may be processed and stored downhole (e.g., within the wellbore 14), while some of the data may be sent to the surface 74 (e.g., in real time). In certain embodiments, the subterranean fluid control system 106 may use information obtained from petroleum system modeling operations, ad hoc assertions from the operator, empirical historical data (e.g., case study reservoir data) in combination with or lieu of the data to determine certain properties of the reservoir fluid 50.

As shown, the memory 132 includes a predictive model 140 and a training system 142. In general, the predictive model 140 is a model trained to determine a predicted condition based on input data corresponding to a current or previous condition. For example, the predictive model 140 may receive an input such as image data indicating multiple measured fluid properties within a subterranean formation. As such, the predictive model 140 may determine a predicted fluid property or indicating a change of the measured fluid properties at a later time t. Further, the predictive model 140 may be capable of receiving additional inputs, such as a time input corresponding to the time that the user desires to determine the respective properties. As such, the predictive model 140 may output a predicted measured fluid property corresponding to the time indicated by the time input.

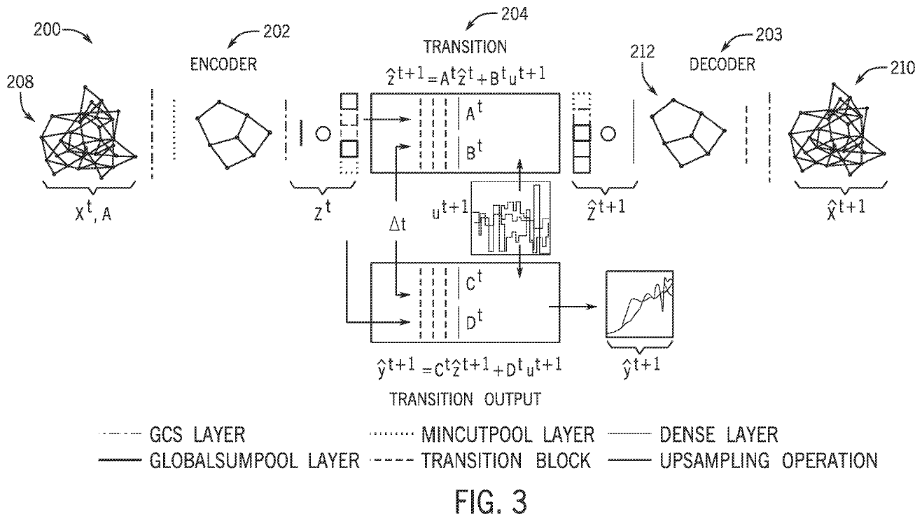

The training system 142 may generally include one or more modules that facilitate the training of the model. To facilitate discussion of the training system 142, FIG. 3 shows an example of a schematic diagram of a training module 200 used to generate a predictive subterranean model using the graph-based training techniques.

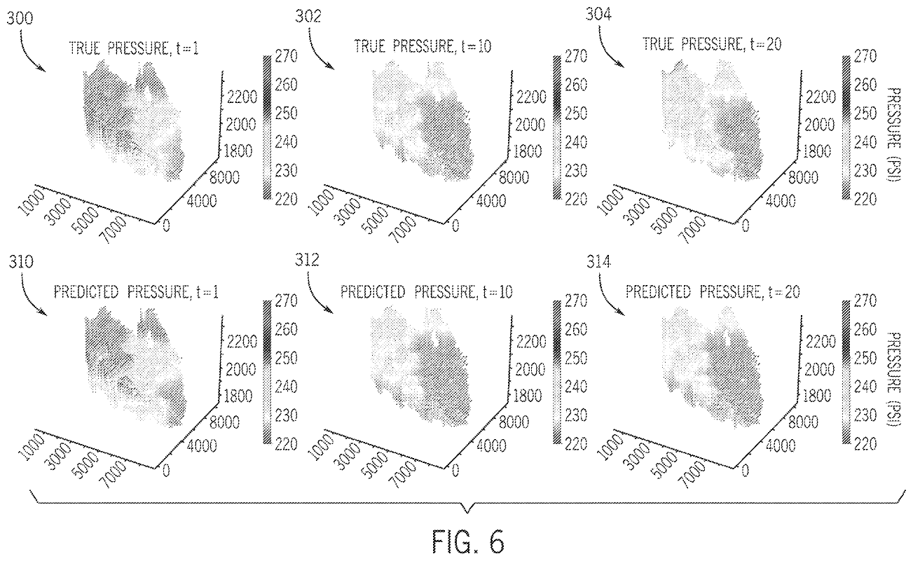

The training module 200 (e.g., proxy model) may include three modules: an encoder module 202, a transition module 204, and a decoder module 206. In general, the training module generates a predictive subterranean model that takes in state of a system (e.g., graph-based representation 208 of image data) and outputs the graph-based representation 210 (e.g., predicted graph-based image, predicted graph-based representation) for a given set of well perturbations. In general, the graph-based representation 210 is an image that corresponds to the next temporal state of the graph-based representation 208. Example graph-based representations 210 are shown and discussed in FIG. 6.

In general, the training module 200 follows an auto-encoder architecture. The encoder module 202 corresponds to the compression step which takes the full resolution image (e.g., graph-based representation 208) and converts it into the latent space dimension using graph convolution and pooling layers. For example, the encoder module 202 may transform a first set of properties of the system-state variables at a high-dimension, x, to a second set of properties of the system-state variables at a low dimension, z. In the latent space, the transition module 204 (e.g., transition layer) may include a connected neural network (e.g., fully connected neural network) that takes the well controls as input and outputs the next temporal state 212 of the simulation variables. This predicted state may then be fed into the decoder module 204, which decompresses the image back into the original resolution. The graph-based representation 210 may represent the next temporal state of pressure and saturation in the physical space. The loss functions incorporate both traditional auto-encoder losses, as well as physics informed loss functions. In some embodiments, the encoder and decoder layers may be built using graph convolution networks.

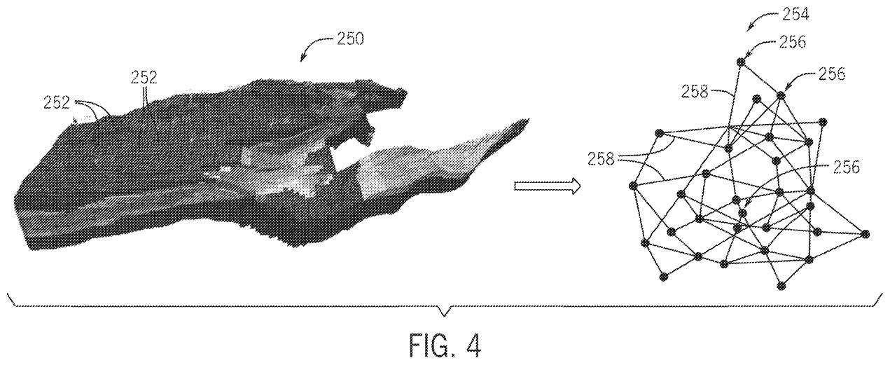

To further illustrate and facilitate the discussion herein, FIG. 4 shows an image 250 corresponding to measure fluid properties of a subterranean formation. In some embodiments, the measured fluid property may include a pressure, a temperature, a saturation, a viscosity, a water content, a fluid composition, a dielectric constant, or other fluid properties of region of the reservoir fluid 50. The image 250 is a three-dimensional (3D) image that includes cells 252. The cells 252 are subsets of the image 250 and correspond to subregions of the subterranean formation that include the reservoir fluid 50. Each cell 252 generally includes one or more neighboring cells that corresponding to adjacent subregions of the subterranean formation.

In accordance with the present disclosure, it may be advantageous to transform the image 250 into a graph format. To illustrate this, the image 254 (e.g., graph-based representation, graph-based image) corresponds to a graph-based representation of the image 250. It should be noted that the image 254 correspond to a subset of the image 250 to better illustrate the relationship between cells 242 of the image 254. The image 254 includes nodes 256 that generally correspond to the cells 252 (e.g., a 1:1 correspondence) of the image 250. However, instead of being a cell having a corresponding value related to a measured fluid property and the cell being part of a larger mesh, the nodes 256 each have the attributes indicating the location (e.g., Cartesian coordinates) of a corresponding cell 252, relational information (e.g., data indicating neighboring cells which is indicated by the branches 258 between the nodes 256), one or more measured fluid property values, and so on. Moreover, because the nodes 256 store relational information and one or more measured fluid property values, the information of the cells 252 of the image 250 is preserved when it is transformed to the graph-base representation illustrated in image 254. As such, rather than preprocessing or postprocessing the image 250, which has a regular or complicated geometry, the model may be trained with each of the nodes 256. In this way, training the model with a graph-based representation uses fewer computational resources as compared to training with a 2D or 3D-dimensional image.

To further illustrate and facilitate the discussion herein, the following description of the network and the operations is given with reference to a subsurface model that contains 23,153 nodes exhibiting a deformed geometry (e.g., non-cuboidal, having non-linear edges, or otherwise having an irregular shape). Three layers from the graph deep learning library, Spektral, were implemented in the encoder and decoder blocks: the GCN layer “GCSConv” (GraphConvSkip) and two pooling layers: one a hierarchical pooling layer, “MinCutPool”, and the second a global pooling layer “GlobalSumPool”. Activation functions were not used in the GCSConv layers or in the MLP layers within the MinCutPool layer. In the E2CO architecture, the encoder module 202 takes as input the adjacency matrix, A, and the feature matrix, containing saturation and pressure values for the current time, t, taken from the physics-based simulator. It outputs the reduced state, a vector whose length equals the latent space dimension, 1. In this example, the encoder module 202 includes two GCSConv layers either side of a MinCutPool layer, which reduces the number of nodes from 23,153 to M=300. The second GCSConv layer has the number of channels set to 1=135 so that the Global SumPool operation that follows subsequently reduces the graph to a single node vector of length 135. The encoder outputs this latent representation vector, the reduced adjacency matrix, and the assignment matrix. The latter two are later used by the decoder to restore the original input structure.

The transition module 204, which stacks several dense layers, takes the latent state representation, the well controls, and the time step size, At, and outputs the predicted latent state, at the next time step following the linear model. The output of the transition layer is input into the decoder module 206 to project the latent state prediction to the original space yielding the scaled state predictions for the next time step. The decoder block consists of a dense layer with 1×K hidden units, where K is the pooled number of nodes, which is then reshaped to a two-dimensional 1×K matrix. This is followed by an up-sampling operation to restore the original graph structure. As a result, there is one final GSCConv layer with the number of channels set to the number of features to be predicted.

Keeping this in mind, the graph convolution network (GCN) autoencoder structure may be shallower than that of the convolutional neural network (CNN) to avoid the oversmoothing phenomenon, whereby nodes across the graph become indistinguishable following too many GCN layers. In practice, most GCN architectures are no deeper than 3 or 4 GCN layers. In contrast, the CNN encoder and decoder may contain ten and five CNN layers, respectively, interspersed with a series of batch normalization and rectified linear unit (relu) activation layers. In the illustrated embodiment, the GNC encoder-decoder (GCN-E2CO) blocks contain 3 GCN layers between them, with no batch normalization or activation functions. The graph based autoencoder structure is far more minimalist, with potential to be made more sophisticated.

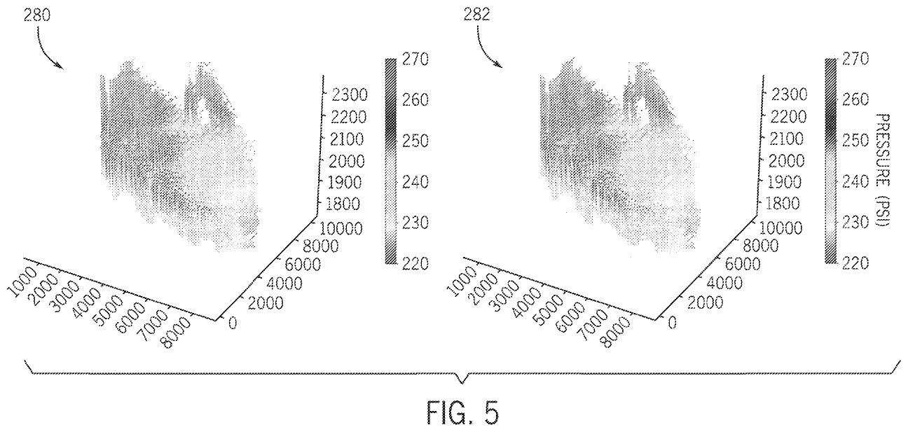

FIG. 5 shows 3D plots (e.g., graph-based representation 280 and 282) of the reservoir graph with a pressure shading map. In general, each graph-based representation 280 and 282 are on a plot that shows a relative size of a reservoir (e.g., x-axis, y-axis, and z-axis). The graph-based representations 280 and 282 include a visual indication (e.g., color or shading) that represents the true pressure distribution. For example, the nodes (e.g., represented as circles in FIG. 5) of the graph-based representations 280 and 282 have a visual indication that generally changes across the graph volume. The graph-based representation 282 is an almost indistinguishable reconstruction produced by the autoencoder of the training module 200 (e.g., shown in FIG. 3) that is trained on duplicates of the graph.

A test was conducted to evaluate the ability of the GCN autoencoder (GCN-AE) to scale to larger reconstruction tasks. The same autoencoder (AE) was trained without the transition blocks for 10 epochs on 50 duplicates of one of the 23,153 node physics-based simulation graphs, and the same graph was subsequently provided to the trained model for reconstruction. The true and reconstructed pressure maps over the 3D reservoir graph are visualized in FIG. 5, demonstrating the success of the GCN-AE in scaling to larger tasks.

As a machine-learning (ML) model is executed for various time steps, the predictive power of the model may be observed. True and predicted pressure distributions for t=1, 10, 20 are plotted on the graph in FIG. 6. Predictions are very accurate for the first two visualized time-steps, and all the time-steps in between, with predicted pressure maps starting to slightly diverge from the true distributions by about t=17. This is expected as the cumulative errors grow as the predictions are made.

To further illustrate the graph-based representation 210, FIG. 6 shows 3D visualizations over time for the true physics-based simulations at times t=1 (e.g., graph-based representation 300), t=10 (e.g., graph-based representation 302), and t=20 (e.g., graph-based representation 304). Additionally, FIG. 6 shows the GCN-E2CO predicted Pressure distributions mapped over the reservoir graph at times t=1 (e.g., graph-based representation 310), t=10 (e.g., graph-based representation 312), and t=20 (e.g., graph-based representation 314) using the disclosed graph-based training techniques. For the first two visualized time-steps, t=1 and t=10, the pressure distributions are seen to be quite accurate. Visualizations of all time-step predictions, though not depicted herein, reveals that intermediate predictions are the most accurate, with barely discernible differences in the pressure maps. More noticeable errors manifest by the final time-steps, including the plotted t=20.

Accordingly, the present disclosure relates to graph-based training techniques for generating a subterranean model indicating one or more measured fluid properties within a subterranean region (e.g., a reservoir), such as subterranean regions with irregular or deformed geometries (e.g., non-cuboidal or other irregular three-dimensional shape). It is noted that certain CNN based models cannot be applied directly to deformed geometry and advanced topographical descriptions, such as pinch outs and non-neighboring connections that are prevalent in any subsurface geological model. In accordance with the present techniques, graph convolution networks can be applied directly on simulation graphs and can perform predictions on deformed geometry directly. Further, CNN based models can be at times inaccurate provided insufficient training data. In the disclosed model, the various state variables can be decoupled to address the multi-physics and multiscale characteristics of the system that needs to be solved. For example, the model may be trained directly with a graph convolution network (GCN) using the deformed geometry coming from the simulation graph. In some embodiments, separate sub-models (e.g., neural networks) may be used to decoupled the various state variables to address the multi-physics and multiscale nature of the problem.

Comparing the training on insufficient data, GCN models may result in more accurate predictions compared to CNN models for deformed geometry. The present approach may be used for various operations including, but not limited to, field development planning for oil and gas reservoirs, history matching and optimization for energy systems, carbon capture and storage applications (e.g., to replace the reservoir simulator), hydrogen storage modeling and optimization, and so on. The disclosed techniques may be used to generate a model that is applicable to three dimensional computational domains. Further, the model may handle deformed geometry, handle non-neighboring connections which is important for CO₂ storage studies, handle complicated structural elements in the simulation domain, and can be used to couple to a numerical simulator to improve the efficiency of the existing technique while resulting in the same accuracy.

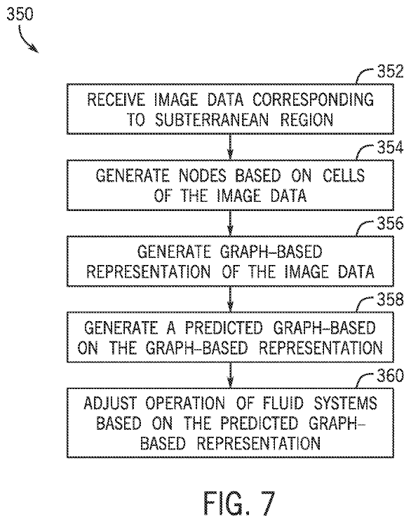

FIG. 7 illustrates an embodiment of a process 350 whereby the processor 130 of the subterranean fluid control system 106 adjusts operation of fluid systems based on a predicted graph-based representation. It should be noted that, although the process 350 is described as being performed by the processor 103, one or multiple processors may perform the process 350. Moreover, the process 350 may be performed by any suitable processor. Further, one or more blocks of the process 350 may be omitted or performed in a different order than as shown in FIG. 7, as discussed in more detail below.

At block 352, the processor 103 receives image data (e.g., the image data 250 described in FIG. 4) corresponding to a subterranean region. In general, the image data may include pixels or voxels corresponding to different spatial regions of a reservoir. Further, the image data may include measured fluid properties corresponding to each pixel or voxels. As described herein, the measured fluid properties may include a pressure, a temperature, a saturation, a viscosity, a water content, a fluid composition, a dielectric constant, or other fluid properties of region of the reservoir fluid.

At block 354, the processor 103 generates nodes based on the cells of the image data. In general, the nodes may preserve the data of the image data, while also consuming relatively fewer computing resources (e.g., processing power, time) to process. For example, it is presently recognized that using node-based data (e.g., the nodes corresponding to the image data) may use fewer computing resources for image data representing subterranean regions having an irregular or deformed geometry.

To present the data of the image data, the nodes may include attributes indicating the spatial location or relative location (e.g., Cartesian coordinates) of corresponding cell(s) of the image data. For example, in some embodiments, the processor 103 may generate nodes in a 1:1 correspondence with the cells of the image data. That is, the processor 103 may generate the same number of nodes as the number of cells. Accordingly, each node may include attributes that indicate the location or spatial arrangement of the corresponding cell of the image data. Further, the attributes may include relational information associated with the corresponding cell(s) of the image data. For example, the relational information for a first node may indicate which nodes represent cells that are adjacent to the cell corresponding to the first node. In some embodiments, the relational information may be indicated by branches connecting each of the nodes.

As discussed herein, the nodes may include measured fluid properties. For example, each node may include data indicating a value of one or more measure fluid properties. In some embodiments, the relational information may indicate changes or trends of the measured fluid property. For example, the relational information may indicate a magnitude of an increase of the fluid property from a first node to a second node (e.g., at least two nodes). In this way, the relational information may indicate how the measured fluid property of the node may vary across the nodes (e.g., one or more adjacent nodes or one or more neighboring nodes). At least in some instances, the relational information may indicate data related to non-neighboring nodes. For example, the relational information may indicate how the measured fluid property changes (e.g., increases or decreases) from a first node to a second node (i.e., adjacent to the first node). Further, the relational information may indicate how the measured property changes from the second node to a third node (i.e., adjacent to the second node and non-neighboring to the first node).

At block 356, the processor 103 generates a graph-based representation (e.g., the image 254) of the image data 250. In general, the graph-based representation of the image data 250 is a combination or aggregation of the nodes representing the cells of the image data 250. For example, the graph-based representation of the image data 250 including 5,000 cells may include 5,000 nodes, where each node includes relational information as discussed above. In some embodiments, the process 350 may stop at block 356. Accordingly, the processor 103 may output the graph-based representation to a computing device that may display the graph-based representation, or use the graph-based representation to train a predictive model, such as a predicted graph-based representation.

At block 358, the processor 103 generates a predicted graph-based representation using the graph-based representation. In general, the processor 103 may perform block 358 in a generally similar manner as illustrated in FIG. 3. For example, the processor 103 may utilize ML algorithms to generate the predicted graph-based representation, such as the graph-based representation 201 in FIG. 3, or the graph-based representations 300, 302, 304, 310, 312, and 314 shown in FIG. 6. To do so, the processor 103 may utilize an auto encoder architecture. In any case, the predicted graph-based representation may indicate a spatial and/or temporal evolution of the measured fluid property relative to the graph-based representation (e.g., an initial graph-based representation). In some embodiments, the processor 103 may utilize one or more fluid models to generate the predicted graph-based representation. For example, the one or more fluid models may include geological process models, petroleum systems models, reservoir dynamics models, equation of state (EOS), or a combination thereof.

In some embodiments, the processor 103 may generate the predicted graph-based representation based on an input indicating a time period. For example, the processor 103 may receive input indicating a time period when it may be desirable to observe the measured fluid property of the graph-based representation. In this way, the predicted graph-based representation may aid users in determining how fluid properties of a reservoir may change over time.

At block 360, the processor 103 adjusts operation of one or more fluid systems (e.g., the fluid system 101 of FIG. 1 and/or the subterranean control system 106 of FIG. 2) using the predicted graph-based representation. In some embodiments, adjusting the operation of the fluid systems may include outputting an alert or displaying a notification (e.g., on the display 136 or another suitable display). For example, the processor 103 may output an alert indicating a time period when a measured fluid property of a reservoir exceeds a threshold or is within a threshold range. In some embodiments, adjusting the operation of the fluid systems may include adjusting a position of valves. For example, the subterranean fluid control system 106 of FIG. 2 may utilize the predicted graph-based representation to control operation of the components or equipment associated with fluid systems, such as opening or closing valves, actuating probes, and the like.

Accordingly, transforming image data into the graph-based representation may utilize relatively less computational resources for generating predictive fluid models. In turn, the graph-based representations may be used to adjust operating parameters of drilling systems and/or fluid systems, develop drilling plans, make adjustments to existing wells, or a combination thereof.

Accordingly, the present disclosure is directed to techniques related to predictive model-based control using fluid properties. In general, the techniques include generating a graph-based representation of image data. As discussed herein, the graph-based representation may utilize fewer computational resources to determine how the measured fluid properties change spatially and temporally. Further, technical effects of the disclosure include a proxy model using physics informed machine learning and graph networks, a proxy model that uses simulation data to train a model, and coupling workflow with a numerical simulator. In some embodiments, the disclosed techniques may be used to train a cloud native ML model and deployed on certain digital platforms.

While the embodiments set forth in this disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform] ing [a function] ... ” or “step for [perform]ing [a function] ... ”, it is intended that such elements are to be interpreted under 35 U.S.C. 112(f). However, for any claims containing elements designated in any other manner, it is intended that such elements are not to be interpreted under 35 U.S.C. 112(f).

1. A method comprising:
receiving image data comprising a plurality of cells corresponding to a plurality of measured fluid properties of a subterranean region;
generating a plurality of nodes based on the plurality of cells, wherein each node of the plurality of nodes comprises relational information related to at least a portion of an arrangement of the plurality of cells;
generating a graph-based representation of the plurality of cells based on the plurality of nodes;
generating a predicted graph-based representation of one or more fluid properties of the subterranean region over time based on a model of fluid properties in the subterranean region and the graph-based representation; and
adjusting one or more operations of one or more fluid systems associated with the subterranean region based on the predicted graph-based representation.

2. The method of claim 1, wherein the subterranean region comprises an irregular or deformed geometry.

3. The method of claim 1, wherein each node of the plurality of nodes corresponds to a cell of the plurality of cells.

4. The method of claim 1, wherein the relational information related to at least a portion of the arrangement of the plurality of cells indicates a change in the plurality of measured fluid properties between at least two cells of the plurality of cells.

5. The method of claim 1, wherein the relational information related to at least a portion of the arrangement of the plurality of cells indicates a spatial arrangement of the plurality of cells within the image data.

6. The method of claim 1, wherein the relational information comprises a branch connecting two nodes of the plurality of nodes.

7. The method of claim 1, further comprising:
receiving a time period; and
generating the predicted graph-based representation that corresponds to the time period.

8. The method of claim 1, wherein the model is trained using a plurality of graph-based representations of the subterranean region.

9. A non-transitory, computer-readable medium storing instructions executable by a processor of a computing device, wherein the instructions comprise instructions to:
receive image data comprising a plurality of cells corresponding to a plurality of measured fluid properties of a subterranean region;
generate a plurality of nodes based on the plurality of cells, wherein each node of the plurality of nodes comprises relational information related to at least a portion of an arrangement of the plurality of cells;
generate a graph-based representation of the plurality of cells based on the plurality of nodes;
generate a predicted graph-based representation of one or more fluid properties of the subterranean region over time based on a model of fluid properties in the subterranean region and the graph-based representation; and
adjust one or more operations of one or more fluid systems associated with the subterranean region based on the predicted graph-based representation.

10. The non-transitory, computer-readable medium of claim 9, wherein the model of fluid properties comprises an equation of state model.

11. The non-transitory, computer-readable medium of claim 9, wherein the instructions to generate a predicted graph-based representation comprise utilizing an auto-encoder architecture to generate the predicted graph-based representation.

12. The non-transitory, computer-readable medium of claim 9, wherein the relational information indicates a change in the plurality of measure fluid properties between a node of the plurality of nodes and one or more non-neighboring nodes of the plurality of nodes relative to the node.

13. The non-transitory, computer-readable medium of claim 9, wherein the relational information indicates a change in the plurality of measure fluid properties between a node of the plurality of nodes and one or more nodes of the plurality of nodes that are adjacent to the node.

14. The non-transitory, computer-readable medium of claim 9, wherein the plurality of measured fluid properties comprise saturation, pressure, or both.

15. The non-transitory, computer-readable medium of claim 9, wherein the instructions to generate a predicted graph-based representation comprise utilizing a machine-learning (ML) model to generate the predicted graph-based representation.

16. The non-transitory, computer-readable medium of claim 9, wherein the instructions to generate a predicted graph-based representation comprise predicting a spatial evolution of the plurality of measure fluid properties over a period of time.

17. A system, comprising:
at least one memory; and
at least one processor configured to execute stored instruction to perform actions comprising:
receiving image data comprising a plurality of cells corresponding to a plurality of measured fluid properties of a subterranean region;
generating a plurality of nodes based on the plurality of cells, wherein each node of the plurality of nodes comprises relational information related to at least a portion of an arrangement of the plurality of cells;
generating a graph-based representation of the plurality of cells based on the plurality of nodes;
generating a predicted graph-based representation of one or more fluid properties of the subterranean region over time based on a model of fluid properties in the subterranean region and the graph-based representation; and
adjusting one or more operations of one or more fluid systems associated with the subterranean region based on the predicted graph-based representation.

18. The system of claim 17, wherein the plurality nodes comprise attributes indicating the plurality of measured fluid properties corresponding to the plurality of cells.

19. The system of claim 17, wherein the one or more processors are configured to generate a predicted graph-based representation by utilizing an auto-encoder architecture to generate the predicted graph-based representation.

20. The system of claim 17, where the plurality of nodes comprise data indicating a spatial location that corresponds to the plurality of cells.
